(19) United States
(12) Patent Application Publication
(10) Pub. No.: US 2016/0141372 A1
(43) Pub. Date: May 19, 2016

(54) Ga2O3 SEMICONDUCTOR ELEMENT

(71) Applicants: TAMURA CORPORATION, Tokyo (JP); NATIONAL INSTITUTE OF INFORMATION AND COMMUNICATIONS TECHNOLOGY, Tokyo (JP)

(72) Inventors: Kohei SASAKI, Nerima-ku, Tokyo (JP); Masataka HIGASHIWAKI, Koganei-shi, Tokyo (JP)

(73) Assignees: TAMURA CORPORATION, Nerima-ku, Tokyo (JP); National Institute of Information and Communicatio ns Technology, Koganei-shi, Tokyo (JP)

(21) Appl. No.: 14/898,529

(22) PCT Filed: Apr. 25, 2014
(86) PCT No.: PCT/JP2014/061798

§ 371 Date: Dec. 15, 2015

(30) Foreign Application Priority Data
Jun. 17, 2013 (JP) 2013-126849

(51) Int. Cl. H01L 29/24; H01L 29/78; H01L 23/31; H01L 29/04; H01L 23/29

(52) U.S. Cl. CPC H01L 29/24; H01L 29/045; H01L 23/291; H01L 23/3171; H01L 29/78

(57) ABSTRACT

Provided is a Ga₂O₃-based semiconductor element having less leak current and a large on/off ratio. In one embodiment, provided is a Ga₂O₃-based MISFET having a β-Ga₂O₃ single crystal layer formed on a high-resistance β-Ga₂O₃ substrate, a source electrode and drain electrode formed on the β-Ga₂O₃ single crystal layer, a gate electrode formed between the source electrode and drain electrode on the β-Ga₂O₃ single crystal layer, and an insulating film that has an oxide insulator as the primary component and that covers the surface of the β-Ga₂O₃ single crystal layer at the region between the drain electrode and the gate electrode and the region between the gate electrode and the source electrode.

### TECHNICAL FIELD

The invention relates to a Ga₂O₃ -based semiconductor element.

### BACKGROUND ART

An element using β-Ga₂O₃ crystal film formed on a β-Ga₂O₃ substrate is known as a conventional Ga₂O₃ -based semiconductor element (see, e.g., PTL 1). Ga₂O₃ has breakdown field strength more than other semiconductor materials such as Si, GaN or SiC, and it is possible to form an ultra-high voltage electronic device by using Ga₂O₃.

According to PTL 1, in, e.g., a β-Ga₂O₃ -based MESFET (Metal-Semiconductor Field Effect Transistor), an off-leakage current between a drain electrode and a source electrode is from 3×10⁻⁶ to 4×10⁻⁶A and an on/off ratio (a ratio of current I_{DS} flowing from the source electrode to the drain electrode when voltage V_{GS} between the gate electrode and the source electrode is 0V with respect to the current I_{DS} flowing at the voltage V_{GS} of −20V) is about four digits.

### CITATION LIST

### Patent Literature

[PTL 1]

WO 2013/035842 A1

### SUMMARY OF INVENTION

### Technical Problem

It is an object of the invention to provide a Ga₂O₃ -based semiconductor element that has a less leak current and a large on/off ratio.

### Solution to Problem

According to one embodiment of the invention, a Ga₂O₃-based semiconductor element set forth in [1] to [6] below is provided so as to achieve the above object.

[1] A Ga₂O₃ -based semiconductor element, comprising:
a β-Ga₂O₃ single crystal layer formed on a β-Ga₂O₃ substrate;
a source electrode and a drain electrode that are formed on the β-Ga₂O₃ single crystal layer;
a gate electrode formed between the source electrode and the drain electrode on the β-Ga₂O₃ single crystal layer; and
a passivation film comprising an oxide insulator as a primary component and covering a region between the source electrode and the gate electrode and a region between the gate electrode and the drain electrode on a surface of the β-Ga₂O₃ single crystal layer.

[2] The Ga₂O₃ -based semiconductor element according to [1], wherein the gate electrode is formed on the β-Ga₂O₃ single crystal layer via a gate insulating film.

[3] The Ga₂O₃ -based semiconductor element according to [2], wherein the passivation film and the gate insulating film comprise a same material and are integrally formed.

[4] The Ga₂O₃ -based semiconductor element according to [1], wherein the gate electrode is formed directly on the β-Ga₂O₃ single crystal layer.

[5] The Ga₂O₃ -based semiconductor element according to any one of [1] to [4], wherein the passivation film comprises (AlₓGa₁₋ₓ)₂O₃ (0<x≦1) as a main component.

[6] The Ga₂O₃ -based semiconductor element according to [5], wherein the passivation film comprises Al₂O₃ as a main component.

[7] The Ga₂O₃ -based semiconductor element according to any one of [1] to [4], wherein the passivation film is in contact with the source electrode and the drain electrode.

### Advantageous Effects of the Invention

According to the invention, a Ga₂O₃-based semiconductor element can be provided that has a less leak current and a large on/off ratio.

### BRIEF DESCRIPTION OF DRAWINGS

FIG. 1 is a vertical cross sectional view showing a Ga₂O₃ -based MISFET in a first embodiment.

FIG. 2A is a vertical cross sectional view showing a process of manufacturing the Ga₂O₃-based MISFET in the first embodiment.

FIG. 2B is a vertical cross sectional view showing the process of manufacturing the Ga₂O₃-based MISFET in the first embodiment.

FIG. 2C is a vertical cross sectional view showing the process of manufacturing the Ga₂O₃-based MISFET in the first embodiment.

FIG. 2D is a vertical cross sectional view showing the process of manufacturing the Ga₂O₃-based MISFET in the first embodiment.

FIG. 2E is a vertical cross sectional view showing the process of manufacturing the Ga₂O₃-based MISFET in the first embodiment.

FIG. 3 is a graph showing a relation between donor concentration and thickness of depletion layer in a β-Ga₂O₃ single crystal layer when gate voltage is 0V.

FIG. 4A is a graph showing I_{DS}-V_{DS} characteristics of the Ga₂O₃ -based MISFET in the first embodiment.

FIG. 4B is a graph showing I_{DS}-V_{DS} characteristics of the Ga₂O₃ -based MISFET in the first embodiment.

FIG. 5A is a graph showing I_{DS}-V_{GS} characteristics of the Ga₂O₃ -based MISFET in the first embodiment.

FIG. 5B is a graph showing I_{DS}-V_{GS} characteristics of the Ga₂O₃ -based MISFET in the first embodiment.

FIG. 6 is a graph showing I_{DS}-V_{GS} characteristics of a MESFET as Comparative Example.

FIG. 7 is a cross sectional view showing a Ga₂O₃ -based MISFET in a second embodiment.

FIG. 8 is a cross sectional view showing a Ga₂O₃ -based MESFET in a third embodiment.

### DESCRIPTION OF EMBODIMENTS

### First Embodiment

The Ga₂O₃ -based semiconductor element in the first embodiment is a Ga₂O₃ -based MISFET (Metal Insulator Semiconductor Field Effect Transistor) having a planar gate structure.

### Configuration of Ga₂O₃ -Based Semiconductor Element

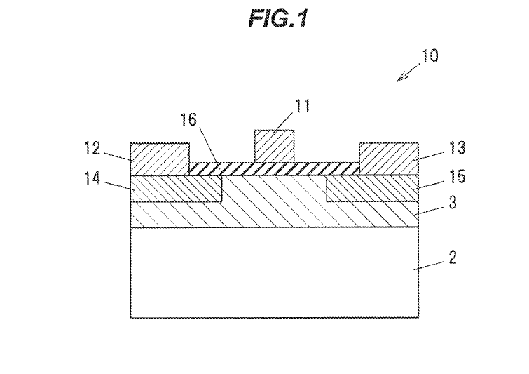

FIG. 1 is a vertical cross sectional view showing a Ga₂O₃ -based MISFET in the first embodiment. A Ga₂O₃-based MISFET 10 includes a β-Ga₂O₃ single crystal layer 3 formed on a high-resistance β-Ga₂O₃ substrate 2, a source electrode 12 and a drain electrode 13 which are formed on the β-Ga₂O₃ single crystal layer 3, a gate electrode 11 formed on the β-Ga₂O₃ single crystal layer 3 via an insulating film 16 in a region between the source electrode 12 and the drain electrode 13, and a source region 14 and a drain region 15 which are formed in the β-Ga₂O₃ single crystal layer 3 respectively under the source electrode 12 and the drain electrode 13.

The high-resistance β-Ga₂O₃ substrate 2 is a β-Ga₂O₃ substrate of which resistance is increased by adding a p-type dopant such as Mg, H, Li, Na, K, Rb, Cs, Fr, Be, Ca, Sr, Ba, Ra, Mn, Fe, Co, Ni, Pd, Cu, Ag, Au, Zn, Cd, Hg, Tl, Pb, N or P.

Plane orientation of the principal surface of the high-resistance β-Ga₂O₃ substrate 2 is not specifically limited but a plane rotated by not less than 50° and not more than 90° with respect to a (100) plane is preferable. In other words, in the high-resistance β-Ga₂O₃ substrate 2, an angle θ(0<θ≦90°) formed between the principal surface and the (100) plane is preferably not less than 50°. The plane rotated by not less than 50° and not more than 90° with respect to the (100) plane is, e.g., a (010) plane, a (001) plane, a (−201) plane, a (101) plane and a (310) plane.

When the principal surface of the high-resistance β-Ga₂O₃ substrate 2 is a plane rotated by not less than 50° and not more than 90° with respect to the (100) plane, it is possible to effectively suppress re-evaporation of raw materials of the β-Ga₂O₃ crystal from the high-resistance β-Ga₂O₃ substrate 2 at the time of epitaxially growing the β-Ga₂O₃ crystal on the β-Ga₂O₃ substrate 2. In detail, where a percentage of the re-evaporated raw material during growth of the β-Ga₂O₃ crystal at a growth temperature of 500° C. is defined as 0%, the percentage of the re-evaporated raw material can be suppressed to not more than 40% when the principal surface of the high-resistance β-Ga₂O₃ substrate 2 is a plane rotated by not less than 50° and not more than 90° with respect to the (100) plane. It is thus possible to use not less than 60% of the supplied raw material to form the β-Ga₂O₃ crystal, which is preferable from the viewpoint of growth rate and manufacturing cost of the β-Ga₂O₃ crystal.

The β-Ga₂O₃ crystal has a monoclinic crystal structure and typically has lattice constants of a=12.23 Å, b=3.04 Å, c=5.80 Å, α=γ=90° and β=103.7°. In the β-Ga₂O₃ crystal, the (100) plane comes to coincide with a (310) plane when rotated by 52.5° around a c-axis and comes to coincide with a (010) plane when rotated by 90°. Meanwhile, the (100) plane comes to coincide with a (101) plane when rotated by 53.8° around a b-axis, comes to coincide with a (001) plane when rotated by 76.3° and comes to coincide with a (−201) plane when rotated by 53.8°.

Alternatively, the principal surface of the high-resistance β-Ga₂O₃ substrate 2 may be a plane rotated at an angle of not more than 37.5° with respect to the (010) plane. In this case, an interface between the insulating film 16 and the β-Ga₂O₃ single crystal layer 3 becomes steep since the surface of the β-Ga₂O₃ single crystal layer 3 can be flattened at the atomic level, allowing more effective suppression of leakage.

The β-Ga₂O₃ single crystal layer 3 is an n-type β-Ga₂O₃ single crystal layer containing an n-type dopant such as Sn, Ti, Zr, Hf, V, Nb, Ta, Mo, W, Ru, Rh, Ir, C, Si, Ge, Pb, Mn, As, Sb, Bi, F, Cl, Br or I. The β-Ga₂O₃ single crystal layer 3 functions as a channel layer of the Ga₂O₃ -based MISFET 10. The thickness of the β-Ga₂O₃ single crystal layer 3 is, e.g., about 10 to 1000 nm.

The gate electrode 11, the source electrode 12 and the drain electrode 13 are formed of, e.g., a metal such as Au, Al, Ti, Sn, Ge, In, Ni, Co, Pt, W, Mo, Cr, Cu and Pb, an alloy containing two or more of such metals, or a conductive compound such as ITO, or alternatively, may have a two-layer structure composed of two different metals, e.g., Ti/Al, Ti/Au, Ti/Pt, Al/Au, Ni/Au, Au/Ni.

The insulating film 16 is an insulating film consisting mainly of an oxide such as (AlₓGa₁₋ₓ)₂O₃ (0<x≦1), SiO₂, HfO₂ or ZrO₂, or a multilayer film formed by laminating two or more insulting films respectively consisting mainly of different oxides selected from the oxides listed. Meanwhile, the insulating film 16 is mostly amorphous but may be partially or entirely crystallized. The insulating film 16 is formed between the source electrode 12 and the drain electrode 13. In the insulating film 16, a portion directly below the gate electrode 11 functions as a gate insulating film, and portions covering a region between the source electrode 12 and the gate electrode 11 and a region between the gate electrode 11 and the drain electrode 13 on the surface of the β-Ga₂O₃ single crystal layer 3 function as a passivation film. In other words, in the first embodiment, the gate insulating film and the passivation film are integrally formed of the same material.

The inventors of the present application found that, when leakage occurs in an element having a high-resistance Ga₂O₃ substrate, a leakage current tends to flow on a surface of a channel layer. Based on this, in the first embodiment, the surface of the β-Ga₂O₃ single crystal layer 3 functioning as a channel layer is covered with the insulating film 16 to suppress the leakage.

Then, it was found that an effect of suppressing leakage current by a passivation film in the embodiments is significantly greater than an effect of suppressing leakage current by a passivation film in an element in which leakage current is likely to flow inside a substrate, e.g., in a transistor having a Si substrate.

The insulating film 16 functioning as a passivation film to suppress leakage is preferably formed of a material which has a high breakdown field strength and is less likely to form interface states at an interface with the β-Ga₂O₃ single crystal layer 3.

Examples of the material having a high breakdown field strength includes nitride insulators such as SiN or AlN, in addition to oxides. However, if the surface of the β-Ga₂O₃ single crystal layer 3 formed of an oxide is covered with the insulating film 16 formed of a nitride material, many interface states are formed at an interface therebetween and may become a leakage source since the insulating film 16 and the β-Ga₂O₃ single crystal layer 3 are formed of different types of materials.

On the other hand, when an oxide is used as a material of the insulating film 16, it is predicted that interface states are less likely to be formed at the interface since the insulating film 16 and the β-Ga₂O₃ single crystal layer 3 are formed of the same type of materials. Among the oxides, Al₂O₃ has particularly good compatibility with Ga₂O₃, allowing a (AlₓGa₁₋ₓ)₂O₃ mixed crystal film to be formed. (AlₓGa₁₋ₓ)₂O₃ containing not only Al₂O₃ but also Ga can be also used as the material of the insulating film 16.

Use of (AlₓGa₁₋ₓ)₂O₃ (0<x≦1) as the material of the insulating film 16 allows element characteristics to be controlled in a wide range. In detail, since the breakdown field strength of the insulating film 16 increases with increasing the percentage of Al (x is closer to 1), it is possible to improve voltage resistance characteristics of the Ga₂O₃ -based MISFET 10 and also possible to reduce gate leakage current. On the other hand, since the crystal structure of the insulating film 16 becomes closer to the crystal structure of the β-Ga₂O₃ single crystal layer 3 with increasing the percentage of Ga (x is closer to 0), it is possible to reduce dangling bonds on the surface of the β-Ga₂O₃ single crystal layer 3 and to further reduce interface states.

Meanwhile, it is known that it is possible to form a high-quality film from Al₂O₃ when using the atomic layer deposition (ALD) method. The ALD method is a film formation method excellent in coatability as compared to other manufacturing methods and can realize a high-quality interface. In addition, the ALD method is excellent in film thickness controllability on a large area and is thus expected to provide high mass productivity. Among (AlₓGa₁₋ₓ)₂O₃ (0<x≦1), Al₂O₃ (x=1), which can realize a high interface leakage reduction effect and high mass productivity by using the ALD method, is therefore particularly preferable as the material of the insulating film 16.

The portion of the insulating film 16 functioning as a passivation film preferably covers as large area of the surface of the β-Ga₂O₃ single crystal layer 3 as possible, and is preferably in contact with the source electrode 12 and the drain electrode 13.

The source region 14 and the drain region 15 are regions with high n-type dopant concentration formed in the β-Ga₂O₃ single crystal layer 3 and are respectively connected to the source electrode 12 and the drain electrode 13. The depth of the source region 14 and the drain region 15 is, e.g., 150 nm. In addition, the average n-type dopant concentration in the source region 14 and the drain region 15 is, e.g., 5×10¹⁹ cm⁻³.

The n-type dopant mainly contained in the source region 14 and the drain region 15 may be the same as or different from the n-type dopant contained in the β-Ga₂O₃ single crystal layer 3. The source region 14 and the drain region 15 may not be included in the Ga₂O₃-based MISFET 10.

The Ga₂O₃ -based MISFET 10 can be a normally-on type or a normally-off type depending on the donor concentration and the thickness of the β-Ga₂O₃ single crystal layer 3 directly below the gate.

Where the Ga₂O₃ -based MISFET 10 is a normally-on type, the source electrode 12 is electrically connected to the drain electrode 13 via the β-Ga₂O₃ single crystal layer 3. Therefore, if a voltage is applied between the source electrode 12 and the drain electrode 13 when a voltage is not applied to the gate electrode 11, a current will flow from the source electrode 12 to the drain electrode 13. On the other hand, when the voltage is applied to the gate electrode 11, a depletion layer is formed in the β-Ga₂O₃ single crystal layer 3 in a region under the gate electrode 11 and a current will not flow from the source electrode 12 to the drain electrode 13 even if the voltage is applied between the source electrode 12 and the drain electrode 13.

Where the Ga₂O₃ -based MISFET 10 is a normally-off type, a current will not flow when the voltage is not applied to the gate electrode 11 even if the voltage is applied between the source electrode 12 and the drain electrode 13. On the other hand, when the voltage is applied to the gate electrode 11, the depletion layer in the β-Ga₂O₃ single crystal layer 3 in the region under the gate electrode 11 is narrowed, and a current will flow from the source electrode 12 to the drain electrode 13 if the voltage is applied between the source electrode 12 and the drain electrode 13.

An example of the method of manufacturing the Ga₂O₃ -based MISFET in the first embodiment will be described below.

### Method of Manufacturing Ga₂O₃ -Based Semiconductor Element

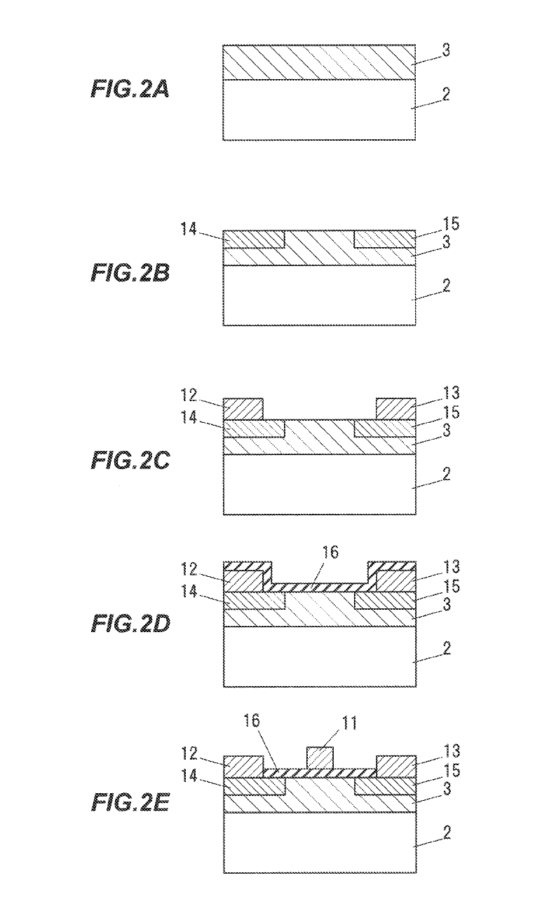

FIGS. 2A to 2E are vertical cross sectional views showing a process of manufacturing the Ga₂O₃ -based MISFET in the first embodiment.

Firstly, as shown in FIG. 2A, the β-Ga₂O₃ single crystal layer 3 is formed on the high-resistance β-Ga₂O₃ substrate 2. To obtain the high-resistance β-Ga₂O₃ substrate 2, for example, a Fe-doped high-resistance β-Ga₂O₃ crystal is grown by a floating zone method and is then sliced and polished to a desired thickness. A principal surface of the high-resistance β-Ga₂O₃ substrate 2 is, e.g., a (010) plane.

The β-Ga₂O₃ single crystal layer 3 is formed by, e.g., a PLD (Pulsed Laser Deposition) method, a CVD (Chemical Vapor Deposition) method, or a MBE (Molecular Beam Epitaxy) method.

The method of introducing an n-type dopant into the β-Ga₂O₃ single crystal layer 3 is, e.g., a method in which an n-type dopant is implanted into a grown β-Ga₂O₃ single crystal film by an ion implantation method, or a method in which β-Ga₂O₃ single crystal film containing an n-type dopant is epitaxially grown.

In using the former method, for example, a 300 nm-thickβ-Ga₂O₃ single crystal film is homoepitaxially grown on the high-resistance β-Ga₂O₃ substrate 2 using the molecular beam epitaxy method and Si ions are then implanted into the entire surface thereof at multiple stages. Here, when adjusting the implantation depth to 300 nm and the average concentration of the implanted Si to 3×10¹⁷ cm⁻³, the normally-on Ga₂O₃ -based MISFET 10 is obtained. Meanwhile, when adjusting, e.g., the implantation depth to 300 nm and the average concentration of the implanted Si to 1×10¹⁶ cm⁻³, the normally-off Ga₂O₃-based MISFET 10 is obtained.

In using the latter method, for example, a 300 nm-thick β-Ga₂O₃ single crystal film containing Sn is homoepitaxially grown on the high-resistance β-Ga₂O₃ substrate 2 using the molecular beam epitaxy method. Here, when adjusting the Sn doping amount to, e.g., 7×10¹⁷ cm⁻³, the normally-on Ga₂O₃ -based MISFET 10 is obtained. Meanwhile, when adjusting the Sn doping amount to, e.g., 1×10¹⁶ cm⁻³, the normally-off Ga₂O₃ -based MISFET 10 is obtained.

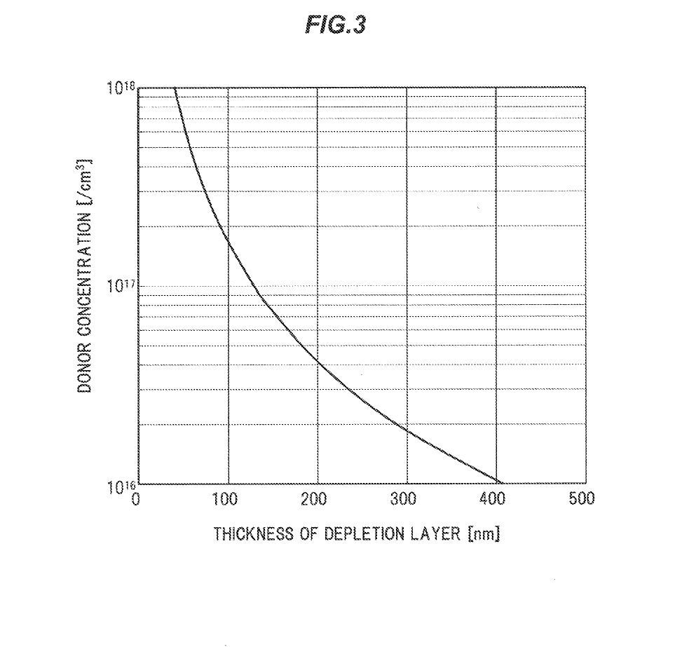

FIG. 3 is a graph showing a relation between donor concentration and thickness of depletion layer in the β-Ga₂O₃ single crystal layer 3 when gate voltage is 0V. A material of the gate electrode 11 is Pt (a barrier height of 1.5 eV) and a relative permittivity of β-Ga₂O₃ is assumed as 10. According to FIG. 3, when the donor concentration is, e.g., 3×10¹⁷ cm⁻³, the thickness of the depletion layer at the gate voltage of 0V is about 90 nm. This shows that the normally-on Ga₂O₃ -based MISFET 10 is obtained when the thickness of the channel layer is more than 90 nm and the normally-off Ga₂O₃ -based MISFET 10 is obtained when thinner than 90 nm.

Next, as shown in FIG. 2B, an n-type dopant such as Si is introduced into the β-Ga₂O₃ single crystal layer 3 by multistage ion implantation to form the source region 14 and the drain region 15.

The n-type dopant is selectively implanted into the β-Ga₂O₃ single crystal layer 3 using, e.g., a mask formed by photolithography. After the implantation, the n-type dopant implanted into the β-Ga₂O₃ single crystal layer 3 is activated by activation annealing treatment in a nitrogen atmosphere at 925° C. for 30 minutes.

Next, as shown in FIG. 2C, the source electrode 12 and the drain electrode 13 are formed on the β-Ga₂O₃ single crystal layer 3. The source electrode 12 and the drain electrode 13 are respectively connected to the source region 14 and the drain region 15.

For example, after forming a mask pattern on the β-Ga₂O₃ single crystal layer 3 by photolithography, a metal film such as Ti/Au is deposited on the entire surface of the β-Ga₂O₃ single crystal layer 3, the mask pattern and the metal film thereon are then removed by lift-off, and the source electrode 12 and the drain electrode 13 are thereby formed. After forming the source electrode 12 and the drain electrode 13, the electrodes are subjected to annealing treatment in, e.g., a nitrogen atmosphere at 450° C. for 1 minute. An ohmic contact is obtained between the β-Ga₂O₃ single crystal layer 3 and the source electrode 12/the drain electrode 13 by this annealing treatment.

Next, as shown in FIG. 2D, a material consisting mainly of an oxide insulator such as Al₂O₃ is deposited on the entire surface of the β-Ga₂O₃ single crystal layer 3, thereby forming the insulating film 16.

The insulating film 16 is obtained by forming a 20 nm-thick Al₂O₃ film on the entire surface of the β-Ga₂O₃ single crystal layer 3 by the ALD (Atomic Layer Deposition) method using an oxidizing agent such as oxygen plasma. Alternatively, another method such as CVD method or PVD (Physical Vapor Deposition) method may be used to form the insulating film 16 instead of using the ALD method.

Next, as shown in FIG. 2E, the gate electrode 11 is formed on the β-Ga₂O₃ single crystal layer 3 via the insulating film 16. The gate electrode 11 is formed between the source electrode 12 and the drain electrode 13.

For example, after forming a mask pattern on the insulating film 16 by photolithography, a metal film such as Ti/Pt is deposited on the entire surface of the insulating film 16, the mask pattern and the metal film thereon are then removed by lift-off, and the gate electrode 11 is thereby formed.

After forming the gate electrode 11, the insulating film 16 on the source electrode 12 and the drain electrode 13 is removed by dry etching etc., to expose the source electrode 12 and the drain electrode 13.

An example of the evaluation result of the Ga₂O₃ -based MISFET in the first embodiment will be described below. The high-resistance β-Ga₂O₃ substrate 2 having a (010) plane as the principal surface was evaluated.

### Evaluation of Ga₂O₃ -Based Semiconductor Element

The following is I_{DS}-V_{DS} characteristics and I_{DS}-V_{GS} characteristics of the Ga₂O₃ -based MISFET 10 when forming the β-Ga₂O₃ single crystal layer 3 by a method in which a β-Ga₂O₃ single crystal film is formed and an n-type dopant is then implanted thereinto by an ion implantation method (hereinafter, referred to as “a first method”) and when forming the β-Ga₂O₃ single crystal layer 3 by another method in which a β-Ga₂O₃ single crystal film containing an n-type dopant is epitaxially grown (hereinafter, referred to as “a second method”).

In the first method, after growing a 300 nm-thick β-Ga₂O₃ single crystal film not containing a dopant by the molecular beam epitaxy method, Si ions were implanted into the entire surface thereof at multiple stages to form a low Si doping concentration region with a depth of 300 nm and an average Si concentration of 3×10¹⁷ cm⁻³, thereby obtaining the β-Ga₂O₃ single crystal layer 3. The gate length and the gate width of the gate electrode 11 were respectively 2 μm and 500 μm, and a distance between the source electrode 12 and the drain electrode 13 was 20 μm.

Meanwhile, in the second method, a 300 nm-thick β-Ga₂O₃ single crystal film containing Sn was grown by the molecular beam epitaxy method. The Sn doping amount was 7×10¹⁷ cm⁻³. The gate length and the gate width of the gate electrode 11 were respectively 4 μm and 500 μm, and a distance between the source electrode 12 and the drain electrode 13 was 20 μm.

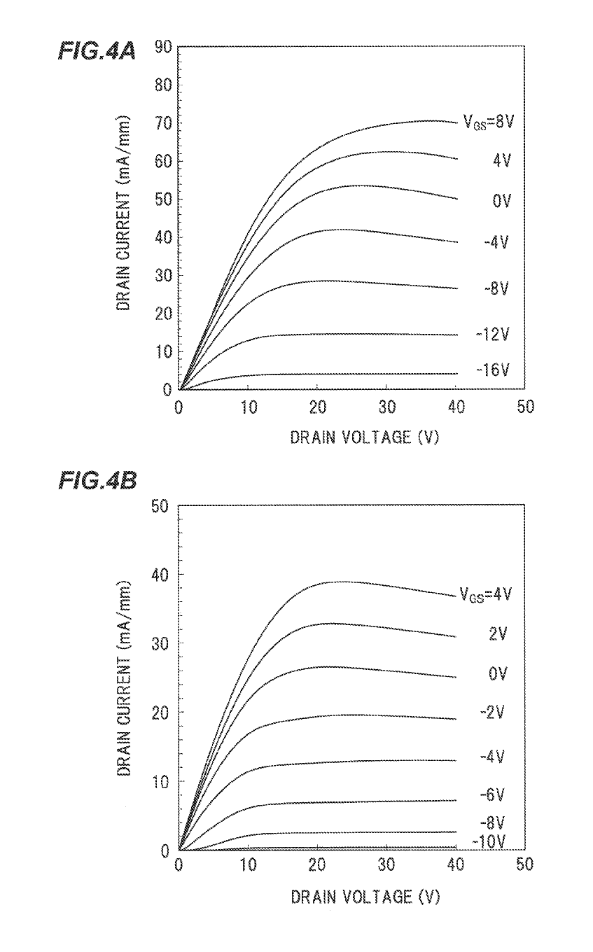

FIG. 4A is a graph showing I_{DS}-V_{DS} characteristics when the β-Ga₂O₃ single crystal layer 3 is formed by the first method, and FIG. 4B is a graph showing I_{DS}-V_{DS} characteristics when the β-Ga₂O₃ single crystal layer 3 is formed by the second method.

I_{DS} here indicates a drain current (a current flowing from the source electrode 12 to the drain electrode 13), and V_{DS} indicates drain voltage (voltage between the drain electrode 13 and the source electrode 12).

FIGS. 4A and 4B both show good rise characteristics and also show that the current I_{DS} is well-modulated by gate voltage V_{GS}. It is considered that this is because the insulating film 16 functioning as a passivation film effectively suppresses leakage current on the surface of the β-Ga₂O₃ single crystal layer 3. The gate voltage V_{GS} here is voltage between the gate electrode 11 and the drain electrode 13.

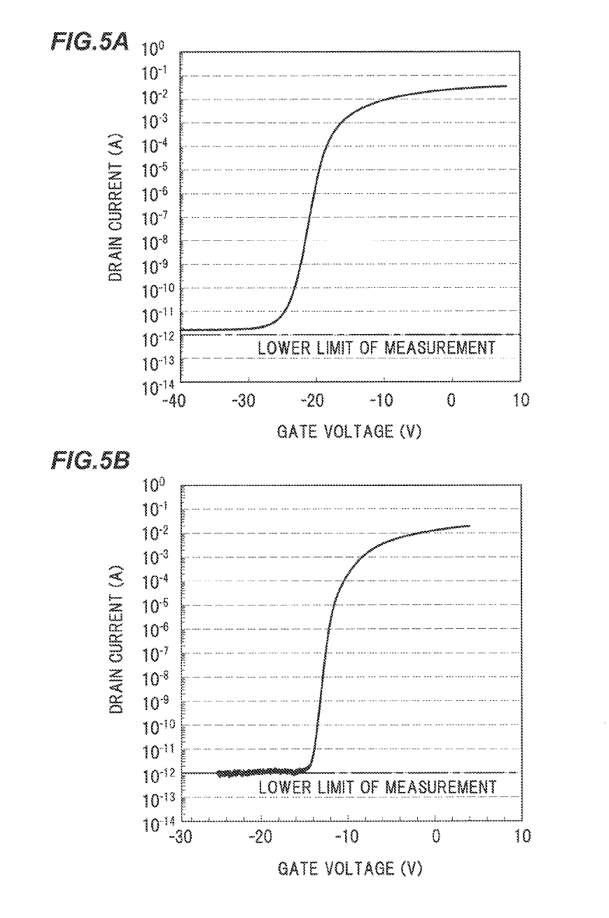

FIG. 5A is a graph showing I_{ID}-V_{GS} characteristics when the β-Ga₂O₃ single crystal layer 3 is formed by the first method, and FIG. 5B is a graph showing I_{DS}-V_{GS} characteristics when the β-Ga₂O₃ single crystal layer 3 is formed by the second method. The drain voltage V_{DS} was 25V in each case.

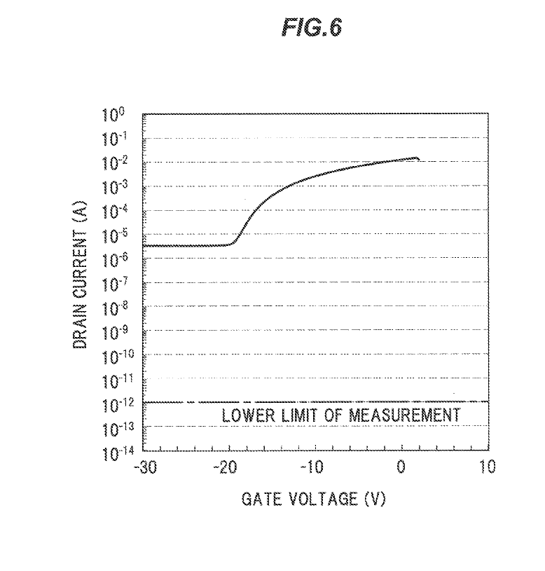

Meanwhile, FIG. 6 is a graph showing I_{DS}-V_{GS} characteristics of a MESFET as Comparative Example. This MESFET as Comparative Example has the same structure as a MESFET not having a passivation film which is disclosed in the previously-mentioned WO 2013/035842. The drain voltage V_{DS} was 40V.

In both FIGS. 5A and 5B, the magnitude of off-leakage current is as very small as about 1×10⁻¹² A, and also, an on/off ratio (a value of a ratio of the magnitude of drain current when the gate is off with respect to the magnitude of drain current when the gate is on) is as very large as not less than ten digits. It is also considered that this is because the insulating film 16 functioning as a passivation film effectively suppresses leakage current on the surface of the β-Ga₂O₃ single crystal layer 3.

On the other hand, FIG. 6 shows that the magnitude of off-leakage current is as relatively large as not less than ×10⁻⁶ A, and also, the on/off ratio is as relatively small as about four digits. One of the reasons is considered that the MESFET as Comparative Example does not have a passivation film.

### Second Embodiment

The second embodiment is different from the first embodiment in that the gate insulating film and the passivation film are formed independently from each other. The explanation of the same features as those in the first embodiment will be omitted or simplified.

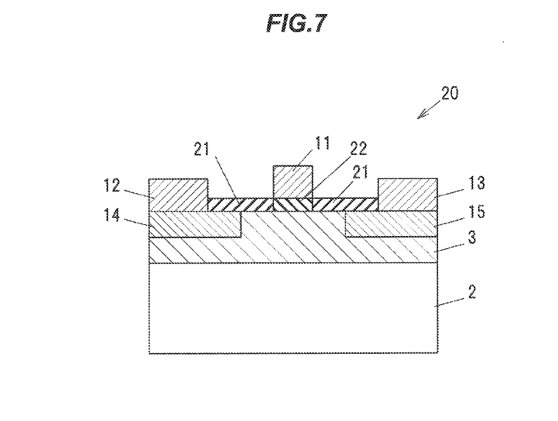

FIG. 7 is a cross sectional view showing a Ga₂O₃ -based MISFET in the second embodiment. A Ga₂O₃ -based MISFET 20 includes the β-Ga₂O₃ single crystal layer 3 formed on the high-resistance β-Ga₂O₃ substrate 2, the source electrode 12 and the drain electrode 13 which are formed on the β-Ga₂O₃ single crystal layer 3, the gate electrode 11 formed on the β-Ga₂O₃ single crystal layer 3 via a gate insulating film 22 in a region between the source electrode 12 and the drain electrode 13, the source region 14 and the drain region 15 which are formed in the β-Ga₂O₃ single crystal layer 3 respectively under the source electrode 12 and the drain electrode 13, and a passivation film 21 covering the surface of the β-Ga₂O₃ single crystal layer 3 at the region between the source electrode 12 and the gate electrode 11 and at the region between the gate electrode 11 and the drain electrode 13.

The passivation film 21 is formed of the same material as the insulating film 16 in the first embodiment. In addition, the passivation film 21 preferably covers as large area of the surface of the β-Ga₂O₃ single crystal layer 3 as possible and is preferably in contact with the source electrode 12 and the drain electrode 13.

A material of the gate insulating film 22 is, e.g., SiO₂, HfO₂, ZrO₂, AlN, SiN or (Al_{y}Ga_{1-y})₂O₃ (0<y≦1) etc. The material of the gate insulating film 22 may be the same as or different from the material of the passivation film 21. Here, forming the gate insulating film 22 using a material having higher permittivity than the material of the passivation film 21 allows gate leakage etc., to be suppressed more effectively than in the Ga₂O₃ -based MISFET 10 of the first embodiment.

The passivation film 21 and the gate insulating film 22 are formed by, e.g., photolithography and etching and it doesn't matter which one is formed first.

The Ga₂O₃ -based MISFET 20 provided with the passivation film 21 has a very small leakage current and a very large on/off ratio in the same manner as the Ga₂O₃ -based MISFET 10 provided with the insulating film 16 in the first embodiment.

### Third Embodiment

The third embodiment is different from the second embodiment in that the Ga₂O₃ -based semiconductor element is a Ga₂O₃ -based MESFET which does not include a gate insulating film. The explanation of the same features as those in the second embodiment will be omitted or simplified.

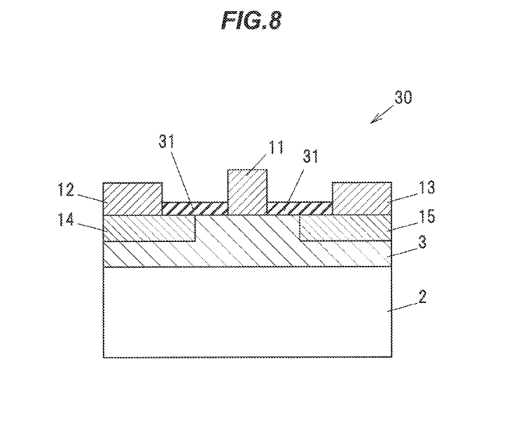

FIG. 8 is a cross sectional view showing a Ga₂O₃ -based MESFET in the third embodiment. A Ga₂O₃ -based MESFET 30 includes the β-Ga₂O₃ single crystal layer 3 formed on the high-resistance β-Ga₂O₃ substrate 2, the source electrode 12 and the drain electrode 13 which are formed on the β-Ga₂O₃ single crystal layer 3, the gate electrode 11 formed directly on the β-Ga₂O₃ single crystal layer 3 in a region between the source electrode 12 and the drain electrode 13, the source region 14 and the drain region 15 which are formed in the β-Ga₂O₃ single crystal layer 3 respectively under the source electrode 12 and the drain electrode 13, and a passivation film 31 covering the surface of the β-Ga₂O₃ single crystal layer 3 at the region between the source electrode 12 and the gate electrode 11 and at the region between the gate electrode 11 and the drain electrode 13.

The passivation film 31 is formed of the same material as the passivation film 21 in the second embodiment. In addition, the passivation film 31 preferably covers as large area of the surface of the β-Ga₂O₃ single crystal layer 3 as possible and is preferably in contact with the source electrode 12 and the drain electrode 13.

The gate electrode 11 forms a Schottky junction with the β-Ga₂O₃ single crystal layer 3 and a depletion layer is formed in the β-Ga₂O₃ single crystal layer 3 under the gate electrode 11.

The Ga₂O₃ -based MESFET 30 can be a normally-on type or a normally-off type depending on the donor concentration and the thickness of the β-Ga₂O₃ single crystal layer 3 directly below the gate.

Where the Ga₂O₃ -based MESFET 30 is a normally-on type, the source electrode 12 is electrically connected to the drain electrode 13 via the β-Ga₂O₃ single crystal layer 3. Therefore, if a voltage is applied between the source electrode 12 and the drain electrode 13 when a voltage is not applied to the gate electrode 11, a current will flow from the source electrode 12 to the drain electrode 13. On the other hand, when the voltage is applied to the gate electrode 11, the depth of the depletion layer under the gate electrode 11 increases and a current will not flow from the source electrode 12 to the drain electrode 13 even if the voltage is applied between the source electrode 12 and the drain electrode 13.

Where the Ga₂O₃ -based MESFET 30 is a normally-off type, a current will not flow when a voltage is not applied to the gate electrode 11 even if a voltage is applied between the source electrode 12 and the drain electrode 13. On the other hand, when the voltage is applied to the gate electrode 11, the depletion layer in the β-Ga₂O₃ single crystal layer 3 in the region under the gate electrode 11 is narrowed, and a current will flow from the source electrode 12 to the drain electrode 13 if the voltage is applied between the source electrode 12 and the drain electrode 13.

The Ga₂O₃ -based MESFET 30 provided with the passivation film 31 has a very small leakage current and a very large on/off ratio in the same manner as the Ga₂O₃ -based MISFET 10 provided with the insulating film 16 in the first embodiment.

### Effects of the Embodiments

According to the first to third embodiments, it is possible to remarkably reduce leakage current and to remarkably improve the on/off ratio by combining a high-resistance β-Ga₂O₃ substrate with a passivation film formed of an oxide insulator. In addition, the transistors in the first to third embodiments have high energy efficiency since occurrence of leakage current is suppressed, thereby realizing energy saving.

Although the embodiments of the invention have been described above, the invention is not to be limited to the above-mentioned embodiments, and the various kinds of modifications can be implemented without departing from the gist of the invention. For example, the Ga₂O₃ -based semiconductor element has been described as an n-type semiconductor element in the embodiments, but may be a p-type semiconductor element. In this case, the conductivity type (n-type or p-type) of each member is all inverted.

In addition, constituent elements of the above-mentioned embodiments can be arbitrarily combined without departing from the gist of the invention.

In addition, the invention according to claims is not to be limited to the above-mentioned embodiments. Further, it should be noted that all combinations of the features described in the embodiments are not necessary to solve the problem of the invention.

### INDUSTRIAL APPLICABILITY

The invention provides a Ga₂O₃ -based semiconductor element having a less leak current and a large on/off ratio.

### REFERENCE SIGNS LIST

2: High-Resistance β-Ga₂O₃ Substrate
3: β-Ga₂O₃ Single Crystal Layer
10, 20: Ga₂O₃ -Based Misfet
30: Ga₂O₃ -Based Mesfet
11: Gate Electrode
12: Source Electrode
13: Drain Electrode
16: Insulating Film
21, 31: Passivation Film
22: Gate Insulating Film

1. A Ga₂O₃ -based semiconductor element, comprising:
a β-Ga₂O₃ single crystal layer formed on a β-Ga₂O₃ substrate;
a source electrode and a drain electrode that are formed on the β-Ga₂O₃ single crystal layer;
a gate electrode formed between the source electrode and the drain electrode on the β-Ga₂O₃ single crystal layer; and
a passivation film comprising an oxide insulator as a primary component and covering a region between the source electrode and the gate electrode and a region between the gate electrode and the drain electrode on a surface of the β-Ga₂O₃ single crystal layer.

2. The Ga₂O₃ -based semiconductor element according to claim 1, wherein the gate electrode is formed on the β-Ga₂O₃ single crystal layer via a gate insulating film.

3. The Ga₂O₃ -based semiconductor element according to claim 2, wherein the passivation film and the gate insulating film comprise a same material and are integrally formed.

4. The Ga₂O₃ -based semiconductor element according to claim 1, wherein the gate electrode is formed directly on the β-Ga₂O₃ single crystal layer.

5. The Ga₂O₃ -based semiconductor element according to claim 1, wherein the passivation film comprises (AlₓGa₁₋ₓ)₂O₃ (0<x≦1) as a main component.

6. The Ga₂O₃ -based semiconductor element according to claim 5, wherein the passivation film comprises Al₂O₃ as a main component.

7. The Ga₂O₃ -based semiconductor element according to claim 1, wherein the passivation film is in contact with the source electrode and the drain electrode.

8. The Ga₂O₃ -based semiconductor element according to claim 2, wherein the passivation film comprises (AlₓGa₁₋ₓ)₂O₃ (0<x≦1) as a main component.

9. The Ga₂O₃ -based semiconductor element according to claim 3, wherein the passivation film comprises (AlₓGa₁₋ₓ)₂O₃ (0<x≦1) as a main component.

10. The Ga₂O₃ -based semiconductor element according to claim 4, wherein the passivation film comprises (AlₓGa₁₋ₓ)₂O₃ (0<x≦1) as a main component.

11. The Ga₂O₃ -based semiconductor element according to claim 8, wherein the passivation film comprises Al₂O₃ as a main component.

12. The Ga₂O₃ -based semiconductor element according to claim 9, wherein the passivation film comprises Al₂O₃ as a main component.

13. The Ga₂O₃ -based semiconductor element according to claim 10, wherein the passivation film comprises Al₂O₃ as a main component.

14. The Ga₂O₃ -based semiconductor element according to claim 2, wherein the passivation film is in contact with the source electrode and the drain electrode.

15. The Ga₂O₃ -based semiconductor element according to claim 3, wherein the passivation film is in contact with the source electrode and the drain electrode.

16. The Ga₂O₃ -based semiconductor element according to claim 4, wherein the passivation film is in contact with the source electrode and the drain electrode.
